(19) United States
(12) Patent Application Publication
(10) Pub. No.: US 2022/0035394 A1
(43) Pub. Date: Feb. 3, 2022

(54) REGULATOR

(71) Applicant: SK hynix Inc., Icheon-si Gyeonggi-do (KR)

(72) Inventor: Young Il KIM, Icheon-si Gyeonggi-do (KR)

(73) Assignee: SK hynix Inc., Icheon-si Gyeonggi-do (KR)

(21) Appl. No.: 17/161,360

(22) Filed: Jan. 28, 2021

(30) Foreign Application Priority Data
Jul. 28, 2020 (KR) 10-2020-0094030

(51) Int. Cl. G05F 1/575

(52) U.S. Cl. CPC G05F 1/575

(57) ABSTRACT

The present technology includes a regulator. The regulator includes an input circuit connected between first and second sub circuits connected to an output circuit and a charging circuit. A first feedback path between the output circuit and the second sub circuit is configured to feed back an output voltage as a first feedback voltage and output a sub voltage in response to the first feedback voltage. A second feedback path between the output circuit and the input circuit is configured to feed back the output voltage as a second feedback voltage and output a first divided voltage in response to the second feedback voltage.

### CROSS-REFERENCE TO RELATED APPLICATION

The present application claims priority under 35 U.S.C. § 119(a) to Korean patent application number 10-2020-0094030, filed on Jul. 28, 2020, in the Korean Intellectual Property Office, the entire disclosure of which is incorporated herein by reference.

### BACKGROUND

### 1. Technical Field

The present disclosure relates to a regulator, and more particularly, to a low drop-out regulator.

### 2. Related Art

A low drop-out regulator (LDO) is a device for providing a stable voltage to an electronic device. The LDO regulator has a characteristic of line regulation and load regulation. The line regulation refers to a fluctuation amount of an output voltage according to a fluctuation of an input voltage, and the load regulation refers to the fluctuation amount of the output voltage when the input voltage is constant. Therefore, the LDO regulator is required to output a constant output voltage when the input voltage is constant.

### SUMMARY

A regulator according to an embodiment of the present disclosure may include an input circuit connected between a first node supplied with a power voltage and a second node supplied with a ground voltage, and configured to receive a reference voltage and a first feedback voltage and output a first divided voltage, first and second sub circuits connected to the input circuit in parallel between the first and second nodes to mirror a current, and the second sub circuit configured to output a sub voltage in response to the first divided voltage, an output circuit configured to output an output voltage in response to the sub voltage, a charging circuit configured to charge the output voltage and transmit a second feedback voltage to the input circuit, a first feedback path between the output circuit and the second sub circuit, and configured to feed back the output voltage as the first feedback voltage and output the sub voltage in response to the first feedback voltage, and a second feedback path between the output circuit and the input circuit, and configured to feed back the output voltage as the second feedback voltage and output the first divided voltage in response to the second feedback voltage.

A regulator according to an embodiment of the present disclosure may include a first input group configured to output a divided voltage in response to a first feedback voltage, a second input group configured to adjust the divided voltage in response to a reference voltage and a second feedback voltage, a sub circuit configured to output a sub voltage in response to the divided voltage, an output circuit configured to output an output voltage through an output node in response to the sub voltage, a first feedback path configured to feed back the output voltage as the first feedback voltage and offset a fluctuation amount of the output voltage, and a second feedback path configured to feed back the output voltage as the second feedback voltage and maintain the fluctuation amount of the output voltage.

### BRIEF DESCRIPTION OF THE DRAWINGS

FIG. 1 is a circuit diagram illustrating a regulator according to an embodiment of the present disclosure.

FIG. 2 is a diagram illustrating a feedback path of the regulator.

FIG. 3 is a diagram specifically illustrating a first feedback path of the regulator.

FIG. 4 is a diagram specifically illustrating a second feedback path of the regulator.

FIG. 5 is a diagram specifically illustrating the second feedback path passing through an input circuit.

FIG. 6 is a diagram for specifically illustrating a cascode path of the regulator.

FIG. 7 is a diagram illustrating an output voltage of the regulator.

### DETAILED DESCRIPTION

An embodiment of the present disclosure may provide a regulator capable of minimizing a fluctuation amount of an output voltage when an input voltage is constant.

The present technology may minimize a fluctuation amount of the output voltage output from the regulator.

Same reference numerals refer to same elements throughout the specification. Thus, even though a reference numeral is not mentioned or described with reference to a drawing, the reference numeral may be mentioned or described with reference to another drawing. In addition, even though a reference numeral is not shown in a drawing, it may be mentioned or described with reference to another drawing.

In the description of the present disclosure, the terms “first” and “second” may be used to describe various components, but the components are not limited by the terms. The terms may be used to distinguish one component from another component. For example, a first component may be called a second component and a second component may be called a first component without departing from the scope of the present disclosure.

For reference, an embodiment including additional components may be provided. Furthermore, an active high or active low configuration indicating an active state of a signal or circuit may be changed depending on embodiments. Furthermore, the configuration of a transistor required for implementing the same function may be modified. That is, the configuration of the PMOS transistor and the configuration of the NMOS transistor may be replaced with each other, depending on a specific situation. If necessary, various transistors may be applied to implement the configurations.

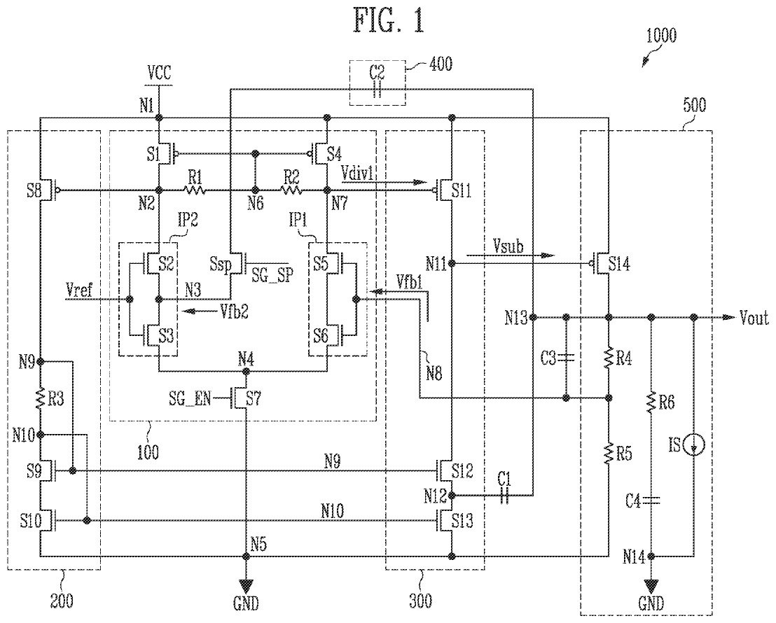

FIG. 1 is a circuit diagram illustrating a regulator according to an embodiment of the present disclosure.

Referring to FIG. 1, the regulator 1000 is a circuit that outputs a voltage having a constant level even though a level of an input voltage is changed. There are various types of the regulator 1000 according to a use, and in the present embodiment, a low drop-out regulator (LDO) of which a voltage loss between an input voltage and an output voltage is small is described as an example.

A structure of the regulator 1000 is described with reference to FIG. 1 as follows.

The regulator 1000 according to the present embodiment may include an input circuit 100, a first sub circuit 200, a second sub circuit 300, a charging circuit 400, and an output circuit 500.

The input circuit 100 may be configured to output a divided voltage Vdiv1 in response to a reference voltage Vref and a first feedback voltage Vfb1. The input circuit 100 may be connected between a first node N1 to which a power voltage VCC is supplied and a fifth node N5 to which a ground voltage GND is supplied. The input circuit 100 may be configured so that a circuit to which the reference voltage Vref is input and a circuit to which the first feedback voltage Vfb1 is input are symmetrical to each other. For example, the input circuit 100 may include first to seventh switches S1 to S7.

The first to third switches S1 to S3 may be connected in series between first and fourth nodes N1 and N4. The first switch S1 may be connected between first and second nodes N1 and N2, and may be implemented with a PMOS transistor that is turned on or turned off in response to a voltage of a sixth node N6. The second and third switches S2 and S3 may be connected between the second and fourth nodes N2 and N4, and may be implemented with NMOS transistors that are simultaneously turned on or turned off in response to the reference voltage Vref. A split switch Ssp may be further connected to a third node N3 between the second and third switches S2 and S3. The split switch Ssp may be implemented with an NMOS transistor capable of connecting or disconnecting the third node N3 and the charging circuit 400 to or from each other in response to a split signal SG_SP, and may be omitted according to the regulator 1000. The words “simultaneous” and “simultaneously” as used herein with respect to occurrences mean that the occurrences take place on overlapping Intervals of time. For example, if a first occurrence takes place over a first interval of time and a second occurrence takes place simultaneously over a second interval of time, then the first and second intervals at least partially overlap each other such that there exists a time at which the first and second occurrences are both taking place.

The fourth to sixth switches S4 to S6 may be connected in series between the first and fourth nodes N1 and N4. The fourth switch S4 may be connected between first and seventh nodes N1 and N7, and may be implemented with a PMOS transistor that is turned on or turned off in response to a voltage of the sixth node N6. The fifth and sixth switches SS and S6 may be connected between the seventh and fourth nodes N7 and N4, and may be implemented with NMOS transistors that are simultaneously turned on or turned off in response to the first feedback voltage Vfb1. The seventh switch S7 may be implemented with an NMOS transistor that connecting or disconnecting the fourth node N4 and the fifth node N5 to or from each other in response to an enable signal SG_EN.

First and second resistors R1 and R2 may be connected in series between the second node N2 and the seventh node N7, and the first and second resistors R1 and R2 may generate a first divided voltage Vdiv1 by dividing a voltage applied to the second node N2. The first divided voltage Vdiv1 may be transferred to the seventh node N7. The sixth node N6 between the first and second resistors R1 and R2 may be commonly connected to gates of the first and fourth switches S1 and S4. Therefore, a turn-on level of the first and fourth switches S1 and S4 may be adjusted according to a resistance values of the first and second resistors R1 and R2.

In the above-described input circuit 100, the fifth and sixth switches S5 and S6 may configure a first input group IP1, and the second and third switches S2 and S3 may configure a second input group IP2. The first feedback voltage Vfb1 may be commonly applied to gates of the fifth and sixth switches S5 and S6 included in the first input group IP1. When the split switch Ssp is turned on, a second feedback voltage Vfb2 may be applied to the third node N3 of the second input group IP2.

The seventh switch S7 may be connected between the fourth and fifth nodes N4 and N5. The ground voltage GND may be supplied to the fifth node N5, and the seventh switch S7 may be implemented with an NMOS transistor capable of forming a current path between the fourth node N4 and the fifth node N5 in response to the enable signal SG_EN.

The first and second sub circuits 200 and 300 may be connected to the input circuit 100 in parallel between the first and fifth nodes N1 and N5 to be configured to mirror a current.

The first sub circuit 200 may include eighth to tenth switches S8 to S10 connected in series between the first and fifth nodes N1 and N5, and may further include a third resistor R3 connected between the eighth and ninth switches S8 and S9. The eighth switch S8 may be connected between first and ninth nodes N1 and N9, and may be implemented with a PMOS transistor capable of connecting or disconnecting the first node N1 and the ninth node N9 to or from each other in response to a voltage of the second node N2. The third resistor R3 may be connected between ninth and tenth nodes N9 and N10. The ninth switch S9 may be connected between the tenth node N10 and the tenth switch S10, and the tenth switch S10 may be connected between the ninth switch S9 and the fifth node N5. A gate of the ninth switch S9 may be connected to the ninth node N9, and a gate of the tenth switch S10 may be connected to the tenth node N10.

The second sub circuit 300 may include eleventh to thirteenth switches Sib to S13 connected in series between the first and fifth nodes N1 and N5. The eleventh switch Sib may be connected between first and eleventh nodes N1 and N11, and may be implemented with a PMOS transistor capable of connecting or disconnecting the first node N1 and the eleventh node N11 to or from each other in response to the first divided voltage Vdiv1 applied to the seventh node N7. The twelfth switch S12 may be connected between eleventh and twelfth nodes N11 and N12, and the thirteenth switch S13 may be connected between the twelfth node N12 and the fifth node N5. A gate of the twelfth switch S12 may be connected to the ninth node N9, and a gate of the thirteenth switch S13 may be connected to the tenth node N10. When the eleventh to thirteenth switches S11 to S13 are turned on, a sub voltage Vsub may be applied to the eleventh node N11. The sub voltage Vsub may have a positive voltage level according to a current generated when the eleventh to thirteenth switches S11 to S13 are turned on.

The charging circuit 400 may be connected between a thirteenth node N13 and the split switch Ssp, and may be implemented with a second capacitor C2. When the split switch Ssp is not present, the charging circuit 400 may be connected between the thirteenth node N13 and the third node N3. The thirteenth node N13 may be a node to which the output voltage Vout is output. Therefore, when the output voltage Vout is applied to the thirteenth node N13, the output voltage Vout may be charged in a second capacitor C2 included in the charging circuit 400 and the voltage charged in the second capacitor C2 may be transmitted to the split switch Ssp or the third node N3. That is, since the second capacitor C2 charges the output voltage Vout and provides the charged voltage to the split switch Ssp or the third node N3, a voltage of the third node N3 may be maintained to be constant.

A first capacitor C1 may be connected between twelfth and thirteenth nodes N12 and N13. When the output voltage Vout is applied to the thirteenth node N13, the first capacitor C1 may charge the output voltage Vout and transmit the charged voltage to the twelfth node N12.

A third capacitor C3 may be connected between thirteenth and eighth nodes N13 and N8. When the output voltage Vout is applied to the thirteenth node N13, the output voltage Vout may be charged in the third capacitor C3 and then applied to gates of the fifth and sixth switches S5 and S6 through the eighth node N8.

The output circuit 500 may include a fourteenth switch S14, fourth to sixth resistors R4 to R6, a fourth capacitor C4, and a current source IS. The fourteenth switch S14 may be connected between the first and thirteenth nodes N1 and N13, and may be implemented with a PMOS transistor capable of connecting or disconnecting the first and thirteenth nodes N1 and N13 to or from each other in response to a voltage of the eleventh node N11. The fourth resistor R4 may be connected between the thirteenth and eighth nodes N13 and N8, and the fifth resistor R5 may be connected between the eighth and fifth nodes N8 and N5. The sixth resistor R6 and the fourth capacitor C4 may be connected in series between thirteenth and fourteenth nodes N13 and N14. For example, the sixth resistor R6 may be connected to the thirteenth node N13, and the fourth capacitor C4 may be connected to the fourteenth node N14. The ground voltage GND may be supplied to the fourteenth node N14. The current source IS may be configured to determine a current flowing from the thirteenth node N13 to the fourteenth node N14.

In the above-described regulator 1000, the output circuit 500 may output the output voltage Vout in response to the reference voltage Vref and the first feedback voltage Vfb1 input to the input circuit 100. When the output voltage Vout is output, the output voltage Vout may be fed back to generate the first feedback voltage Vfb1, and a level of the output voltage Vout may be adjusted by the first feedback voltage Vfb1 input to the input circuit 100. In the present embodiment, the level of the output voltage Vout may be maintained to be constant by the input circuit 100, the second sub circuit 300, the charging circuit 400, and the output circuit 500.

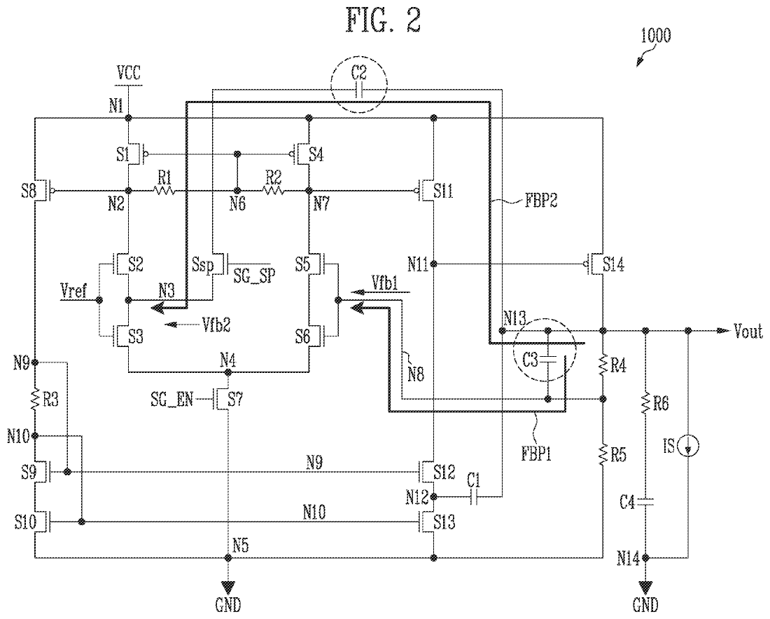

FIG. 2 is a diagram illustrating a feedback path of the regulator.

Referring to FIG. 2, the first to third capacitors C1 to C3 may be connected to the thirteenth node N13 to which the output voltage Vout is applied, and the first to third capacitors C1 to C3 may be included in different paths, respectively.

Since the third capacitor C3 is connected to the eighth node N8 connected to the gates of the fifth and sixth switches S5 and S6, a first feedback path FBP1 connected to the thirteenth node N13, the third capacitor C3, and the eighth node N8 may be formed. The third capacitor C3 may charge the output voltage Vout according to a potential difference between the thirteenth node N13 and the eighth node N8, and when the charge is completed, the first feedback voltage Vfb1 may be transmitted to the eighth node N8. That is, the first feedback voltage Vfb1 may be proportional to the output voltage Vout. For example, when the output voltage Vout is increased, the first feedback voltage Vfb1 is also increased, and thus turn-on levels of the fifth and sixth switches S5 and S6 may be increased. Conversely, when the output voltage Vout is decreased, the first feedback voltage Vfb1 is also decreased, and thus turn-on levels of the fifth and sixth switches S5 and S6 may be decreased. When the turn-on levels of the fifth and sixth switches S5 and S6 are changed, a voltage of the seventh node N7 may be changed.

When the enable signal SG_EN is input to the seventh switch S7, the regulator 1000 may be activated. When the seventh switch S7 is turned on by the enable signal SG_EN and the fifth and sixth switches S5 and S6 are turned on by the first feedback voltage Vfb1, the voltage of the seventh node N7 may be decreased.

Since the second capacitor C2 is connected between the thirteenth node N13 and the third node N3, a second feedback path FBP2 connected to the thirteenth node N13, the second capacitor C2, and the third node N3 may be formed. When the regulator 1000 is activated, a split signal SG_SP may be applied to the split switch Ssp, and thus the second capacitor C2 and the third node N3 may be electrically connected. For example, the split signal SG_SP may be set to be activated or deactivated in synchronization with the enable signal SG_EN. Alternatively, the split signal SG_SP may be set to be deactivated when the enable signal SG_EN is deactivated and set to be activated or deactivated when the enable signal SG_EN is activated. That is, when the second feedback path FB2 is not used, the split signal SG_SP may be deactivated, and when the second feedback path FB2 is used, the split signal SG_SP may be activated. In the present embodiment, since the voltage of the third node N3 is adjusted using the second feedback path FBP2, a state in which the split switch Ssp is turned on is described as a default.

The constant reference voltage Vref may be applied to the gates of the second and third switches S2 and S3, and the reference voltage Vref may be a positive voltage higher than 0V. When the reference voltage Vref is applied to the second and third switches S2 and S3 in a state in which the seventh switch S7 is turned on, the voltage of the third node N3 may be decreased. That is, the first and second feedback paths FB1 and FB2 may be used to adjust the output voltage Vout by adjusting voltages of the input terminals of the input circuit 100 of FIG. 1. The input terminals of the input circuit 100 may include one input terminal including the second and third switches S2 and S3 and another input terminal including the fifth and sixth switches S5 and S6.

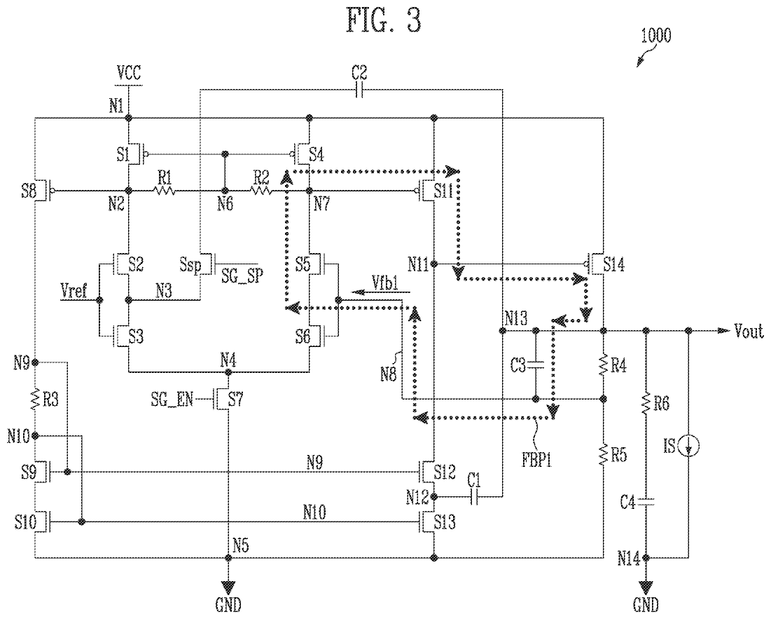

FIG. 3 is a diagram specifically illustrating the first feedback path of the regulator.

Referring to FIG. 3, the first feedback path FBP1 may feed back the output voltage Vout of the thirteenth node N13 as the first feedback voltage Vfb1, and may include a path for adjusting voltages of the seventh, eleventh, and thirteenth nodes N7, N11, and N13 according to the first feedback voltage Vfb1.

When the output voltage Vout is increased, the output voltage Vout may be adjusted to be decreased again according to the first feedback path FBP1. For example, when the first feedback voltage Vfb1 is applied to the eighth node N8, the turn-on levels of the fifth and sixth switches S5 and S6 may be adjusted according to the first feedback voltage Vfb1. Therefore, when the output voltage Vout is increased, the first feedback voltage Vfb1 is increased, and thus the turn-on levels of the fifth and sixth switches S5 and S6 may be increased. Since the seventh switch S7 is turned on and the fourth node N4 is discharged, when the turn-on levels of the fifth and sixth switches S5 and S6 are increased, the voltage of the seventh node N7 may be decreased. Accordingly, a turn-on level of the eleventh switch S11 may be increased. When the turn-on level of the eleventh switch S11 is increased, the power voltage VCC supplied to the first node N1 may be transmitted to the eleventh node N11, and thus the voltage of the eleventh node N11 may be increased. When the voltage of the eleventh node N11 is increased, a turn-on level of the fourteenth switch S14 is decreased, and thus output voltage Vout output through the thirteenth node N13 may be decreased.

When the output voltage Vout is decreased, the output voltage Vout may be adjusted to be increased again according to the first feedback path FBP1. For example, when the first feedback voltage Vfb1 is applied to the eighth node N8, the turn-on levels of the fifth and sixth switches S5 and S6 may be adjusted according to the first feedback voltage Vfb1. Therefore, when the output voltage Vout is decreased, the first feedback voltage Vfb1 is decreased, and thus the turn-on levels of the fifth and sixth switches S5 and S6 may be decreased. When the turn-on levels of the fifth and sixth switches S5 and S6 are decreased, the voltage of the seventh node N7 may be increased. Accordingly, the turn-on level of the eleventh switch S11 may be decreased. When the turn-on level of the eleventh switch S11 is decreased, the voltage of the eleventh node N11 may be decreased. When the voltage of the eleventh node N11 is decreased, a turn-on level of the fourteenth switch S14 is increased, and thus the output voltage Vout output through the thirteenth node N13 may be increased.

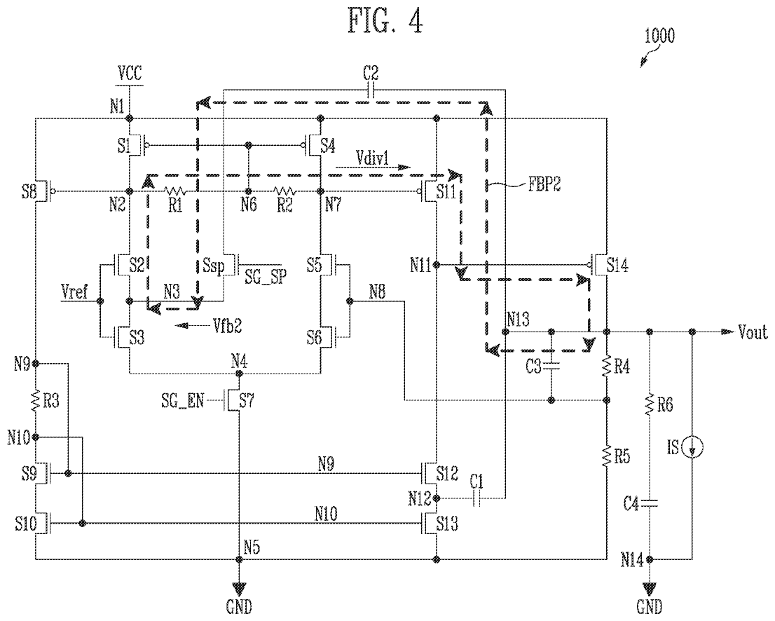

FIG. 4 is a diagram specifically illustrating the second feedback path of the regulator.

Referring to FIG. 4, the second feedback path FBP2 may feed back the output voltage Vout of the thirteenth node N13 as the second feedback voltage Vfb2 through the second capacitor C2, and may include a path for adjusting voltages of the second, sixth, seventh, eleventh, and thirteenth nodes N2, N6, N7, N11, and N13 according to the second feedback voltage Vfb2.

The second feedback path FBP2 does not decrease the output voltage Vout even though the output voltage Vout is increased. For example, when the output voltage Vout is increased in a state in which the split switch Ssp is turned on, a voltage may be charged in the second capacitor C2 by a voltage difference between two electrodes of the second capacitor C2, and the second feedback voltage Vfb2 may be transmitted to the third node N3. Since the second and third switches S2 and S3 are turned on at a constant level in response to the reference voltage Vref, when the second feedback voltage Vfb2 is increased, the voltage of the second node N2 may also be increased. At this time, since a turn-on level of the second switch S2 is maintained to be constant by the reference voltage Vref, the voltage of the second node N2 is not higher than a threshold voltage of the second switch S2. That is, when the output voltage Vout is increased, the voltage of the second node N2 also is increased, but the voltage of the second node N2 may be limited by the threshold voltage of the second switch S2. When a voltage is applied to the second node N2, the first divided voltage Vdiv1 divided by the first and second resistors R1 and R2 may be applied to the seventh node N7. When the voltage of the second node N2 is increased, the first divided voltage Vdiv1 is also increased, and thus the turn-on level of the eleventh switch S11 may be decreased. When the turn-on level of the eleventh switch S11 is decreased, the voltage of the eleventh node N11 may be decreased, and thus the turn-on level of the fourteenth switch S14 may be increased. When the first feedback path FBP1 is not included and only the second feedback path FBP2 is included in the regulator 1000, since a path for decreasing the output voltage Vout when the output voltage Vout is increased is not present, the voltage Vout is not decreased. However, as described with reference to FIG. 3, when the output voltage Vout is increased, since the output voltage Vout is decreased by the first feedback path FBP1, a voltage difference may be offset at the seventh node N7 where the first and second feedback paths FBP1 and FBP2 overlap, and thus the output voltage Vout may be maintained to be constant.

The second feedback path FBP2 does not increase the output voltage Vout even though the output voltage Vout is decreased. For example, when the output voltage Vout is decreased in a state in which the split switch Ssp is turned on, a voltage may be charged in the second capacitor C2 by a voltage difference between two electrodes of the second capacitor C2, and the second feedback voltage Vfb2 may be transmitted to the third node N3. Since the second and third switches S2 and S3 are turned on at a constant level in response to the reference voltage Vref, when the second feedback voltage Vfb2 is decreased, the voltage of the second node N2 may also be decreased. When a voltage is applied to the second node N2, the first divided voltage Vdiv1 divided by the first and second resistors R1 and R2 may be applied to the seventh node N7. When the voltage of the second node N2 is decreased, the first divided voltage Vdiv1 is also decreased, and thus the turn-on level of the eleventh switch S11 may be increased. When the turn-on level of the eleventh switch S11 is increased, the voltage of the eleventh node N11 may be increased, and thus the turn-on level of the fourteenth switch S14 may be decreased. When the first feedback path FBP1 is not included and only the second feedback path FBP2 is included in the regulator 1000, since a path for increasing the output voltage Vout when the output voltage Vout is decreased is not present, the voltage Vout is not increased. However, as described with reference to FIG. 3, when the output voltage Vout is decreased, since the output voltage Vout is increased by the first feedback path FBP1, a voltage difference may be offset at the seventh node N7 where the first and second feedback paths FBP1 and FBP2 overlap, and thus the output voltage Vout may be maintained to be constant.

The second feedback path FBP2 passing through the input circuit is described as follows.

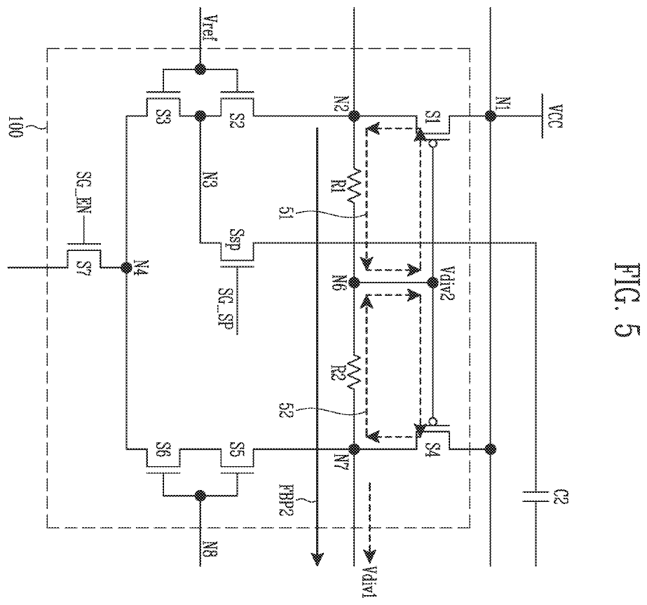

FIG. 5 is a diagram specifically illustrating the second feedback path passing through the input circuit.

Referring to FIG. 5, the first and second resistors R1 and R2 may be included in the second feedback path FBP2 passing through the input circuit 100. Since the first and second resistors R1 and R2 are connected in series between the second and seventh nodes N2 and N7, a second divided voltage Vdiv2 divided by the first and second resistors R1 and R2 may be applied to the sixth node N6 between the first and second resistors R1 and R2.

Since the gates of the first and fourth switches S1 and S4 are commonly connected to the sixth node N6, turn-on levels of the first and fourth switches S1 and S4 may be adjusted according to the second divided voltage Vdiv2. When it is assumed that the first and fourth switches S1 and S4 are configured of transistors of the same size and resistance values of the first and second resistors R1 and R2 are the same, the turn-on level may be equally adjusted by the second divided voltage Vdiv2. Accordingly, since a loop 51 passing through the first switch S1 and the first resistor R1 and a loop 52 passing through the fourth switch S4 and the second resistor R2 are mirrored to each other, a current amount of the second, sixth, and seventh nodes N2, N6, and N7 may be maintained to be constant. Therefore, the first divided voltage Vdiv1 may be maintained at a constant level.

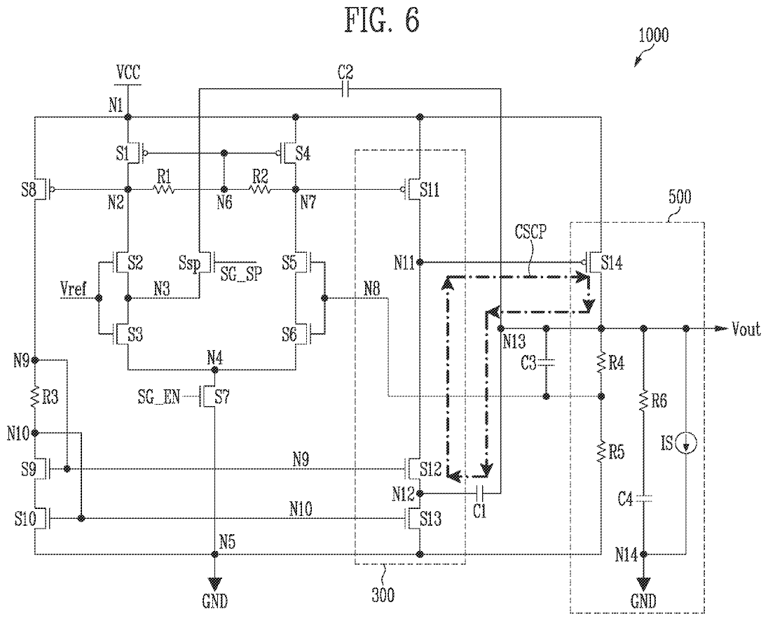

FIG. 6 is a diagram for specifically illustrating a cascode path of the regulator.

Referring to FIG. 6, a cascade path CSCP may be formed between the second sub circuit 300 and the output circuit 500. The cascode path CSCP may be configured with a circuit that amplifies the output voltage Vout, and may be formed as a path to which the thirteenth node N13, the first capacitor C1, the twelfth switch S12, the eleventh node N11, and the fourteenth switch S14 are connected.

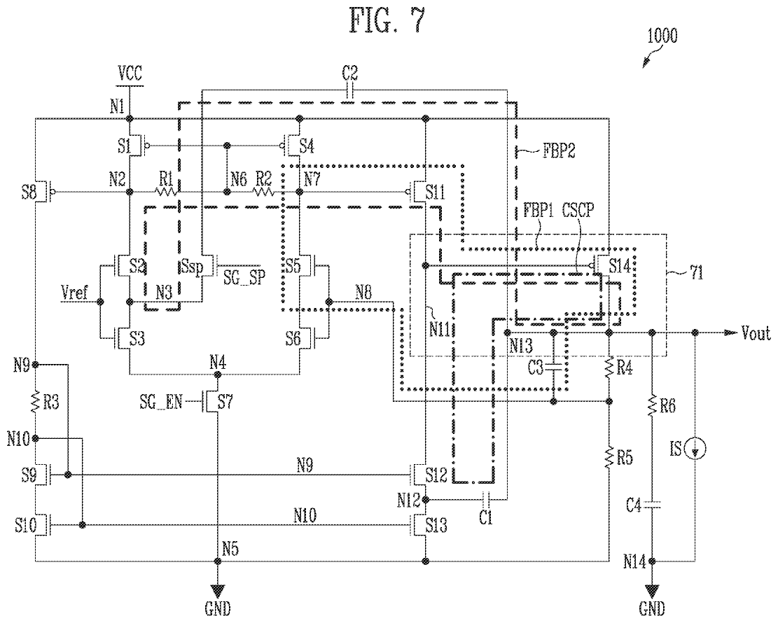

FIG. 7 is a diagram illustrating the output voltage of the regulator.

Referring to FIG. 7, when the regulator 1000 is activated and the first and second feedback paths FBP1 and FBP2 and the cascode path CSCP are formed, the first and second feedback paths FBP1 and FBP2 and the cascode path CSCP may overlap at the thirteenth node N13 in a region 71 where the output voltage Vout is output. Therefore, in the region 71 where the paths overlap, voltage drop and rise of each path may be offset from each other, and thus the output voltage Vout having a constant level may be output.

What is claimed is:

1. A regulator comprising:
an input circuit connected between a first node supplied with a power voltage and a second node supplied with a ground voltage, and configured to receive a reference voltage and a first feedback voltage and output a first divided voltage;
first and second sub circuits connected to the input circuit in parallel between the first and second nodes to mirror a current, and the second sub circuit configured to output a sub voltage in response to the first divided voltage;
an output circuit configured to output an output voltage in response to the sub voltage;
a charging circuit configured to charge the output voltage and transmit a second feedback voltage to the input circuit;
a first feedback path between the output circuit and the second sub circuit, and configured to feed back the output voltage as the first feedback voltage and output the sub voltage in response to the first feedback voltage; and
a second feedback path between the output circuit and the input circuit, and configured to feed back the output voltage as the second feedback voltage and output the first divided voltage in response to the second feedback voltage.

2. The regulator of claim 1, wherein the input circuit comprises:
first, second, and third switches sequentially connected in series between the first node and a third node;
fourth, fifth, and sixth switches sequentially connected in series between the first node and the third node; and
first and second resistors sequentially connected in series between a node between the first and second switches and a node between the fourth and fifth switches.

3. The regulator of claim 2, wherein gates of the first and fourth switches are commonly connected to a node between the first and second resistors.

4. The regulator of claim 2, wherein the second and third switches are commonly turned on or turned off in response to the reference voltage, and
the fifth and sixth switches are commonly turned on or turned off in response to the first feedback voltage.

5. The regulator of claim 1, further comprising:
a seventh switch connected between the input circuit and the second node, and configured to connect or disconnect the input circuit and the second node in response to an enable signal.

6. The regulator of claim 2, wherein the input circuit is connected between the first sub circuit and the second sub circuit, and
the second sub circuit is connected between the input circuit and the output circuit.

7. The regulator of claim 6, wherein the first sub circuit includes an eighth switch, a third resistor, and ninth and tenth switches sequentially connected in series between the first and second nodes,
a gate of the eighth switch is connected to the first resistor,
a gate of the ninth switch is connected to a node between the eighth switch and the third resistor, and
a gate of the tenth switch is connected to a node between the third resistor and the ninth switch.

8. The regulator of claim 7, wherein the second sub circuit includes eleventh, twelfth, and to thirteenth switches sequentially connected in series between the first and second nodes,
a gate of the eleventh switch is connected to the second resistor,
a gate of the twelfth switch is connected to the gate of the ninth switch, and
a gate of the thirteenth switch is connected to the gate of the tenth switch.

9. The regulator of claim 8, wherein the sub voltage is output through a node between the eleventh and twelfth switches.

10. The regulator of claim 8, further comprising:
a first capacitor connected between a node between the twelfth and thirteenth switches and a node from which the output voltage is output.

11. The regulator of claim 4, wherein the charging circuit includes a second capacitor connected between a node from which the output voltage is output and a node between the second and third switches.

12. The regulator of claim 1, wherein the output circuit includes a fourteenth switch, and fourth and fifth resistors sequentially connected in series between the first and second nodes.

13. The regulator of claim 12, wherein the fourteenth switch is configured to connect or disconnect the first node and the fourth resistor in response to the sub voltage, and
the first feedback voltage is output through a node between the fourth and fifth resistors.

14. The regulator of claim 13, further comprising:
a third capacitor connected between the node between the fourth and fifth resistors and a node from which the output voltage is output.

15. A regulator comprising:
a first input group configured to output a divided voltage in response to a first feedback voltage;
a second input group configured to adjust the divided voltage in response to a reference voltage and a second feedback voltage;
a sub circuit configured to output a sub voltage in response to the divided voltage;
an output circuit configured to output an output voltage through an output node in response to the sub voltage;
a first feedback path configured to feed back the output voltage as the first feedback voltage and offset a fluctuation amount of the output voltage; and
a second feedback path configured to feed back the output voltage as the second feedback voltage and maintain the fluctuation amount of the output voltage.

16. The regulator of claim 15, wherein the first input group and the second input group are configured to output the divided voltage in response to the reference voltage, the first feedback voltage, and the second feedback voltage.

17. The regulator of claim 15, wherein the first input group is configured to adjust the divided voltage in response to the first feedback voltage output from the first feedback path, and
the second input group is configured to adjust the divided voltage in response to the second feedback voltage output from the second feedback path.

18. The regulator of claim 15, further comprising:
a first switch connected between a first node to which a power voltage is applied and a first output node of the first input group;
a second switch connected between the first node and a second output node of the second input group; and
first and second resistors connected between the first and second output nodes.

19. The regulator of claim 18, wherein a turn-on level of the first and second switches are adjusted according to a voltage divided by the first and second resistors.
